(19) United States
(12) Patent Application Publication
(10) Pub. No.: US 2021/0408427 A1
(43) Pub. Date: Dec. 30, 2021

(54) DISPLAY PANEL AND DISPLAY DEVICE THEREOF

(71) Applicant: Wuhan China Star Optoelectronics Semiconductor Display Technology Co., Ltd., Wuhan, Hubei (CN)

(72) Inventor: Bo Wang, Wuhan, Hubei (CN)

(73) Assignee: Wuhan China Star Optoelectronics Semiconductor Display Technology Co., Ltd., Wuhan, Hubei (CN)

(21) Appl. No.: 16/770,729

(22) PCT Filed: Jan. 8, 2020
(86) PCT No.: PCT/CN2020/070985

§ 371 Date: Jun. 8, 2020

(30) Foreign Application Priority Data
Aug. 21, 2019 (CN) 201910774572.8

(51) Int. Cl. H01L 51/50; H01L 51/52

(52) U.S. Cl. CPC H01L 51/5056; H01L 51/5072; H01L 2251/306; H01L 2251/308; H01L 51/5234

(57) ABSTRACT

The present invention provides a display panel and a display device thereof. The display panel includes an anode layer, a hole transport layer, a light-emitting layer, an electron transport layer, and a cathode layer. On one aspect, the cathode layer of a transparent region of the present disclosure adopts a single-layer structure composed of a first cathode layer, and a cathode layer of the display region adopts a laminated structure composed of the first cathode layer and a second cathode layer disposed thereon. This can not only improve light transmittance of the transparent region, but also improve luminous efficiency of the display region.

### CROSS REFERENCE TO RELATED APPLICATIONS

The application claims priority to a Chinese patent application filed on Aug. 21, 2019 in the State Intellectual Property Office (SIPO), having application number 201910774572.8, titled “Display Panel and Display Device Thereof”, and the entire contents of which are incorporated herein by reference.

### FIELD OF INVENTION

The present disclosure relates to the field of display technology, and more particularly, to a display panel and a display device thereof.

### BACKGROUND OF INVENTION

Organic light-emitting diodes (OLEDs) are also known as organic electroluminescence display devices, or organic light-emitting semiconductors. A base structure of OLED is a thin and transparent indium tin oxide (ITO) with semiconductor characteristics, which is connected to a positive electrode of electricity, and in addition to add another metal cathode, wrapped into a sandwich-like structure.

First, one characteristics of OLEDs is that they emits light by themselves, which is different from thin film transistor liquid crystal display devices (TFT-LCD), which require a backlight, so that they have high visibility and brightness. Secondly, OLEDs have advantages of low voltage demand, high power saving efficiency, fast response, light weight, thin thickness, simple structure, low cost, wide viewing-angles, almost infinitely high contrast, low power consumption, extremely high response speed, etc., and they have become one of the most important display technologies nowadays and is gradually replacing TFT-LCDs, and they are expected to become the next generation of mainstream display technology after liquid crystal displays (LCDs).

### SUMMARY OF INVENTION

At present, the biggest problem is camera under panel (CUP) in the industry. At present, no matter what kind of display screen, even when it is not displayed, transmittance of the screen is relatively low, and the transmittance of each part of the screen cannot be guaranteed to be same. At present, a transmittance of OLED is greater than a transmittance of LCD. As we all known, the current camera technology has high requirements for various optical lenses and lenses in front of the sensor, so as to be able to truly restore the information mapped by the outside world to the sensor and be relatively accurate, and the information collected is easy to correct external reasoning. Thus, the problem that the camera under panel technology needs to be solved is to improve the transmittance of OLED display panels.

An object of the present disclosure is to provide a display panel and a display device thereof, which can improve the light transmittance of the display panel.

In order to solve the above problems, an embodiment of the present disclosure provides a display panel defining a display region and a transparent region. The display panel comprises an anode layer, a hole transport layer, a light-emitting layer, an electron transport layer, and a cathode layer. Wherein the hole transport layer is disposed on the anode layer, the light-emitting layer is disposed on the hole transport layer, the electron transport layer is disposed on the light-emitting layer, and the cathode layer is disposed on the electron transport layer. Wherein the cathode layer comprises a first portion correspondingly disposed in the display region and a second portion correspondingly disposed in the transparent region, the first portion comprises a first cathode layer and a second cathode layer disposed on the first cathode layer, and the second portion comprises the first cathode layer.

Furthermore, wherein a constituent material of the first cathode layer comprises one or more of transparent conductive oxide or graphene.

Furthermore, wherein the transparent conductive oxide comprises one or more of indium tin oxide (ITO), al-doped ZnO (AZO), or indium zinc oxide (IZO).

Furthermore, wherein a constituent material of the second cathode layer comprises one or more of Ag, Au, Cu, Al, or Mg.

Furthermore, wherein the display panel of the transparent region comprises an inorganic layer, and the inorganic layer is disposed on a surface of the first cathode layer away from the anode layer.

Furthermore, wherein the display panel of the display region comprises an inorganic layer, and the inorganic layer is disposed between the first cathode layer and the second cathode layer.

Furthermore, wherein a constituent material of the inorganic layer comprises one or more of SiN, SiO2, or SiNO.

Furthermore, a thickness of the first cathode layer ranges from 20 nm to 200 nm.

Furthermore, a thickness of the second cathode layer ranges from 8 nm to 30 nm.

Another embodiment of the present disclosure further provides a display device comprising the display panel according to the present disclosure.

The present disclosure relates to a display panel and a display device thereof. On one aspect, a cathode layer of a transparent region of the present disclosure adopts a single-layer structure composed of a first cathode layer, and a cathode layer of the display region adopts a laminated structure composed of the first cathode layer and a second cathode layer disposed thereon. This can not only improve a light transmittance of the transparent region, but also improve the luminous efficiency of the display region. Finally, an inorganic layer is disposed on the first cathode layer in the present disclosure, thereby preventing water and oxygen from invading, and protecting the first cathode layer from being affected when forming the second cathode layer.

### DESCRIPTION OF DRAWINGS

In order to more clearly illustrate the technical solutions of the embodiments of the present invention, the drawings used in the description of the embodiments will be briefly described as below. Obviously, the drawings described as below are just some embodiments of the present invention. For one of ordinary skill in the art, under the premise of no creative labor, other drawings can also be obtained according to these drawings.

FIG. 1 is a schematic structural diagram of a display panel of an embodiment 1 of the present disclosure.

FIG. 2 is a schematic structural diagram of a display panel of an embodiment 2 of the present disclosure.

Figure numerals: display panel 100, display region 101, transparent region 102, anode layer 1, hole transport layer 2, light-emitting layer 3, electron transport layer 4, cathode layer 5, first anode layer 11, second anode layer 12, third anode layer 13, first cathode layer 51, second cathode layer 52, and inorganic layer 6.

### DETAILED DESCRIPTION OF PREFERRED EMBODIMENTS

The preferred embodiments of the present disclosure will be described in detail below with reference to the accompanying drawings in order to completely introduce the technical content of the present disclosure to those skilled in the art, to exemplify that the present disclosure can be implemented, to make the disclosed technical content of the present disclosure more clear, and to make it easier for those skilled in the art to understand how to implement the present disclosure. However, the present disclosure can be embodied by many different forms of embodiments. The protection scope of the present disclosure is not limited to the embodiments mentioned in the content, and the description of the following embodiments is not intended to limit the scope of the present disclosure.

The directional terms described by the present disclosure, such as “upper”, “lower”, “front”, “back”, “left”, “right”, “inner”, “outer”, “side”, etc., are only directions by referring to the accompanying drawings. The directional terms used herein are used to explain and explain the present disclosure, rather than to limit the protection scope of the present disclosure.

In figures, elements with same structures are indicated by same numbers, and elements with similar structures or functions are indicated by similar numbers. In addition, in order to facilitate understanding and description, sizes and thickness of each element shown in the drawings are arbitrarily shown, and the present disclosure does not limit the sizes and thickness of each element.

When elements are described as being “on” another element, the element may be disposed directly on the other element; there may also be an intermediate element, the element is disposed on the intermediate element and the intermediate element is disposed on another element. When an element described as “installed to” or “connected to” another element, both can be understood as being directly “installed” or “connected”, or one element is “mounted to” or “connected to” another element through an intermediate element.

### Embodiment 1

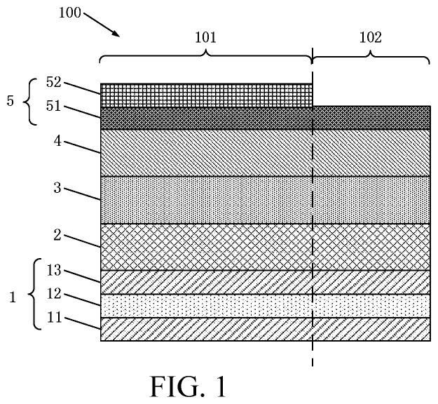

As shown in FIG. 1, a display panel 100 defines a display region 101 and a transparent region 102 and comprises an anode layer 1, a hole transport layer 2, a light-emitting layer 3, an electron transport layer 4, and a cathode layer 5.

As shown in FIG. 1, wherein the anode layer 1 comprises a first anode layer 11, a second anode layer 12, and a third anode layer 13, which are sequentially disposed. Wherein, the first anode layer 11 is made of indium tin oxide (ITO), the second anode layer 12 is made of Ag, and the third anode layer 13 is made of ITO. Wherein, a thickness of the second anode layer 12 is greater than 100 nm, so that it can totally reflect light emitted from the light-emitting layer 3. Thickness of the second anode layer 12 is preferably 150 nm in the present embodiment. The first anode layer 11 and the third anode layer 13. which are made of ITO, can assist the second anode layer 12 to completely reflect the light emitted from the light-emitting layer to the cathode layer, thereby improving light emitting efficiency of the display panel 100.

As shown in FIG. 1, the hole transport layer 2 is disposed on the anode layer 1. Wherein, the hole transport layer 2 is made of one or more of 4,4′,4″-tri[2-naphthylphenylamino]triphenylamine, N,N′-diphenyl-N,N′-(1-naphthyl)-1,1′-Biphenyl-4,4′-diamine, or 4,4′-cyclohexylbis[N, N-bis(4-methylphenyl)aniline], therefore, the hole transport layer 2 can transport holes in the anode layer 1 to the light-emitting layer 3 well. Wherein, the hole transport layer 2 can be formed by vacuum thermal evaporation deposition, and the thickness of the hole transport layer ranges from 40 nm to 150 nm. When the thickness of the hole transport layer 2 is less than 40 nm, an effect of transporting the holes in the anode layer 1 to the light-emitting layer 3 cannot be achieved. When the thickness is greater than 150 nm, it may cause waste of materials and increase production costs. Thus, the thickness of the hole transport layer is preferably 95 nm in the present embodiment.

As shown in FIG. 1, the light-emitting layer 3 is disposed on the hole transport layer 2. Wherein, the light-emitting layer 3 is made of one or more of aniline, 4,4′-(1,4-phenylene-2,1-ethylenediyl)bis[N-(2-ethyl-6-methylphenyl)-N-phenyl, 4,4′-Bis(9-ethyl-3-carbazolevinyl)-1,1′-biphenyl, or bis(2-hydroxyphenylpyridine)beryllium, therefore, the light-emitting layer 3 can combine the holes of the anode layer 1 well and electrons of the cathode layer 5 to produce a light-emitting effect. Wherein, a thickness of the light-emitting layer 3 ranges from 20 nm to 50 nm. If the thickness of the light-emitting layer 3 is less than 20 nm, it may cause a short-circuiting between the anode layer 1 and the cathode layer 5, thereby causing device failure. If the thickness of the light emitting layer 3 is greater than 50 nm, it will cause waste of materials and increase production costs. Thus, the thickness of the light-emitting layer is preferably 35 nm in the present embodiment.

As shown in FIG. 1, the electron transport layer 4 is disposed on the light-emitting layer 3. Wherein, the electron transport layer 4 is made of one or more of 1,3,5-tris(1-phenyl-1H-benzimidazol-2-yl)benzene, 4,7-diphenyl-1,10-phenanthroline, 3,3′-[5′-[3-(3-pyridyl)phenyl][1,1′:3′,1″-terphenyl]-3,3″-diyl]dipyridine, therefore, the electron transport layer 4 can transport the electrons in the cathode layer 5 to the light-emitting layer 3 well. Wherein, the electron transport layer 4 can be formed by vacuum thermal evaporation deposition, and the thickness of the electron transport layer ranges from 20 nm to 80 nm. When the thickness of the electron transport layer 4 is less than 20 nm, an effect of transporting the electrons in the cathode layer 5 to the light-emitting layer 3 cannot be achieved. When the thickness is greater than 80 nm, it may cause waste of materials and increase production costs. Thus, the thickness of the electron transport layer is preferably 50 nm in the present embodiment.

As shown in FIG. 1, the cathode layer 5 is disposed on the electron transport layer 4. Wherein, the cathode layer 5 comprises a first portion correspondingly disposed in the display region 101 and a second portion correspondingly disposed in the transparent region 102, the first portion comprises a first cathode layer 51 and a second cathode layer 52 disposed on the first cathode layer 51, and the second portion only comprises the first cathode layer 51. Wherein, the first cathode layer 51 is made of one or more of transparent conductive oxide or graphene. Specifically, the transparent conductive oxide comprises one or more of indium tin oxide (ITO), al-doped ZnO (AZO), or indium zinc oxide (IZO). The first cathode layer 51 may be formed to a film by a physical vapor deposition (PVD) process, an atomic layer deposition (ALD) process, or a pulse laser deposition (PLD) process, and a thickness of the first cathode layer ranges from 20 nm to 200 nm. If the thickness of the first cathode layer is less than 20 nm, it will cause non-uniformity of the film, resulting in optical quality problems. If the thickness of the first cathode layer is greater than 200 nm, it will reduce mass production efficiency and increase production costs. Thus, the phenomenon that the light transmittance of the display panel 100 is low due to high extinction coefficient of the conventional metal cathode layer 5 can be avoided, thereby improving the light transmittance of the transparent region 102.

Wherein, the second cathode layer is made of one or more of Ag, Au, Cu, Al, or Mg, and the present embodiment preferably adopts an alloy of Ag and Mg. Thus, photons generated in the light-emitting layer 3 can have a certain probability to be reflected back to an optical microcavity in the second cathode layer 52, and the photons reflected back to the microcavity will strengthen in a yin-yang electrode. After reflecting back and forth several times, the photon has the certain probability to transmit through the second cathode layer 52. A spectrum of photon constituent thereof is narrower than a spectrum without reflection, energy is more concentrated, and luminous efficiency is higher. Therefore, the light emitting efficiency of the display panel 100 in the display region 101 can be improved. Wherein, a thickness of the second cathode layer 52 ranges from 8 nm to 30 nm, and the thickness of the second cathode layer is preferably 15 nm. If the thickness of the second cathode layer is less than 8 nm, it will cause non-uniformity of the film, resulting in optical quality problems. If the thickness of the second cathode layer is greater than 30 nm, it will reduce the light transmittance and increase production costs.

### Embodiment 2

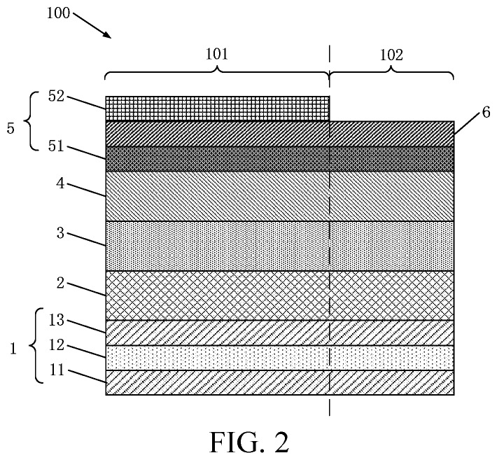

As shown in FIG. 1 and FIG. 2, the present embodiment is different from Embodiment 1 in that: the display panel 100 of the transparent region 102 further comprises an inorganic layer 6, and the inorganic layer 6 is disposed on a surface of the first cathode layer 51 away from the anode layer 1. The display panel 102 of the display region 101 further comprises an inorganic layer 6, and the inorganic layer 6 is disposed between the first cathode layer 51 and the second cathode layer 52.

As shown in FIG. 2, the inorganic layer 6 is disposed on the first cathode layer 51 of the display region 101 and the transparent region 102. Wherein, the inorganic layer 6 is made of one or more of SiN, SiO2, or SiNO. The inorganic layer 6 is preferably made of SiN in the present embodiment, and it can be formed by plasma-enhanced chemical vapor deposition (PECVD). A thickness of the inorganic layer ranges from 0.5 μm to 5 μm, if the thickness of the inorganic layer is less than 0.5 μm, it will cause non-uniformity of the film, resulting in optical quality problems, and if the thickness of the inorganic layer is greater than 5 μm, it will reduce mass production efficiency and increase production costs. Thus, the thickness of the inorganic layer is preferably 1 μm in the present embodiment. By providing the inorganic layer 6, on the one hand, erosion of water and oxygen can be prevented; on the other hand, when the second cathode layer 52 is formed, the first cathode layer 51 can be protected from being affected.

Another embodiment of the present disclosure also provides a display device comprising the display panel 100 according to the present disclosure.

The display panel and the display device provided by the present disclosure have been described in detail above. It should be understood that the exemplary embodiments described herein should be considered only descriptive and are used to help understand the method of the present disclosure and its core ideas, but not to limit the present disclosure. In each exemplary embodiment described features or aspects should be considered similar features generally applicable to other exemplary embodiments or aspects. Although the present disclosure has been described with reference to exemplary embodiments, various changes and modifications may be suggested to those skilled in the art. The present disclosure is intended to cover these changes and modifications within the scope of the appended claims. Any modification, equivalent replacement, and improvement made within the spirit and principle of the present disclosure shall be included in the protection scope of the present disclosure.

What is claimed is:

1. A display panel, defining a display region and a transparent region, comprising:
an anode layer;
a hole transport layer disposed on the anode layer;
a light-emitting layer disposed on the hole transport layer;
an electron transport layer disposed on the light-emitting layer; and
a cathode layer disposed on the electron transport layer;
wherein the cathode layer comprises a first portion correspondingly disposed in the display region and a second portion correspondingly disposed in the transparent region, the first portion comprises a first cathode layer and a second cathode layer disposed on the first cathode layer, and the second portion comprises the first cathode layer.

2. The display panel as claimed in claim 1, wherein a constituent material of the first cathode layer comprises one or more of transparent conductive oxide or graphene.

3. The display panel as claimed in claim 2, wherein the transparent conductive oxide comprises one or more of indium tin oxide (ITO), al-doped ZnO (AZO), or indium zinc oxide (IZO).

4. The display panel as claimed in claim 1, wherein a constituent material of the second cathode layer comprises one or more of Ag, Au, Cu, Al, or Mg.

5. The display panel as claimed in claim 1, wherein the display panel of the transparent region comprises an inorganic layer, and the inorganic layer is disposed on a surface of the first cathode layer away from the anode layer.

6. The display panel as claimed in claim 1, wherein the display panel of the display region comprises an inorganic layer, and the inorganic layer is disposed between the first cathode layer and the second cathode layer.

7. The display panel as claimed in claim 5, wherein a constituent material of the inorganic layer comprises one or more of SiN, SiO2, or SiNO.

8. The display panel as claimed in claim 6, wherein a constituent material of the inorganic layer comprises one or more of SiN, SiO2, or SiNO.

9. The display panel as claimed in claim 1, wherein a thickness of the first cathode layer ranges from 20 nm to 200 nm.

10. The display panel as claimed in claim 1, wherein a thickness of the second cathode layer ranges from 8 nm to 30 nm.

11. A display device, comprising a display panel, wherein the display panel defines a display region and a transparent region and comprises:
an anode layer;
a hole transport layer disposed on the anode layer;
a light-emitting layer disposed on the hole transport layer;
an electron transport layer disposed on the light-emitting layer; and
a cathode layer disposed on the electron transport layer;
wherein the cathode layer comprises a first portion correspondingly disposed in the display region and a second portion correspondingly disposed in the transparent region, the first portion comprises a first cathode layer and a second cathode layer disposed on the first cathode layer, and the second portion comprises the first cathode layer.

12. The display device as claimed in claim 11, wherein a constituent material of the first cathode layer comprises one or more of transparent conductive oxide or graphene.

13. The display device as claimed in claim 12, wherein the transparent conductive oxide comprises one or more of indium tin oxide (ITO), al-doped ZnO (AZO), or indium zinc oxide (IZO).

14. The display device as claimed in claim 11, wherein a constituent material of the second cathode layer comprises one or more of Ag, Au, Cu, Al, or Mg.

15. The display device as claimed in claim 11, wherein the display panel of the transparent region comprises an inorganic layer, and the inorganic layer is disposed on a surface of the first cathode layer away from the anode layer.

16. The display device as claimed in claim 11, wherein the display panel of the display region comprises an inorganic layer, and the inorganic layer is disposed between the first cathode layer and the second cathode layer.

17. The display device as claimed in claim 15, wherein a constituent material of the inorganic layer comprises one or more of SiN, SiO2, or SiNO.

18. The display device as claimed in claim 16, wherein a constituent material of the inorganic layer comprises one or more of SiN, SiO2, or SiNO.

19. The display device as claimed in claim 11, wherein a thickness of the first cathode layer ranges from 20 nm to 200 nm.

20. The display device as claimed in claim 11, wherein a thickness of the second cathode layer ranges from 8 nm to 30 nm.
